(19) United States
(12) Patent Application Publication
(10) Pub. No.: US 2018/0297267 A1
(43) Pub. Date: Oct. 18, 2018

(54) SYSTEM AND METHOD OF MANUFACTURING A CYLINDRICAL NANOIMPRINT LITHOGRAPHY MASTER

(71) Applicant: CARPE DIEM TECHNOLOGIES, INC., Franklin, MA (US)

(72) Inventors: John S. Berg, Mattapoisett, MA (US); John Howard, Ashland, MA (US); Dimitur Benchev, Norwood, MA (US); David A. Waldman, Concord, MA (US)

(21) Appl. No.: 15/951,073

(22) Filed: Apr. 11, 2018

Related U.S. Application Data
(60) Provisional application No. 62/484,089, filed on Apr. 11, 2017.

(51) Int. Cl. B29C 59/02; H01L 21/027; B29C 35/08

(52) U.S. Cl. CPC B29C 59/026; G03F 7/0002; B29C 35/0805; H01L 21/0271

(57) ABSTRACT

A system for manufacturing a cylindrical, nanoimprint lithography master includes, in one embodiment, a flat master coated with a first layer of compliant photopolymer material, a cylindrical master with an outer sleeve formed from a second layer of compliant photopolymer material, and a light source. The cylindrical master is disposed in tangential contact against the flat master such that the first and second layers of compliant material exhibit 5%-20% compressive strain within the region of contact. Through such pressure, the feature pattern in the flat master is imprinted into the first layer of material. Light from the light source is acutely focused into a narrow curing zone within the contact region. Curing causes the first layer of photopolymer material to bond to the outer sleeve. Through geometric matching and synchronized movement between the flat and cylindrical masters, the cylindrical master can be patterned about its periphery without creating a seam.

### BACKGROUND OF THE INVENTION

Integrated circuits for semiconductor devices, such as transistors and microprocessors, have long been fabricated through successive photolithography, masking, and processing steps that are time-consuming and costly. Typically, fabrication is performed on silicon wafers, gallium arsenide wafers, fused silica, quartz, glass and other rigid stable substrates having dimensions that are well-controlled and largely unvarying.

More recently, nanoimprint soft lithography has become a mainstream manufacturing method for defining very fine features (5 nm to microns). In nanoimprint soft lithography, a finely detailed relief pattern mask or embossing shim carries the imprint pattern. The mask is then used to replicate nanoscale features into a photopolymerizable material, photopolymer resist or thermoplastic material that is subsequently cured using ultraviolet (UV) light and/or heat.

Nanoimprint lithography (NIL) is undertaken at a wafer level by disposing a relief pattern, which may be repeating in nature, onto the wafer. More specifically, the pattern is stamped into a thermoplastic material or imprinted into a liquid polymerizable material that is applied to either the wafer or the mask. In the latter case, light produced from an ultraviolet light source is directed through the wafer and is used to irradiate the layer of photopolymer material, resulting in polymerization of the material. The hardened, polymerized material is thereby cured with the detailed relief pattern, and its fine nanoscale features, retained therein. Alternatively, if the wafer material is opaque to ultraviolet light, the embossing shim or patterned mask must be optically transparent to allow for irradiation of the pattern into the layer of photopolymer material from the side of the embossing shim or patterned mask.

The NIL process for patterning flat surfaces, as described above, has been similarly applied to rollers in order to continuously pattern a web or flexible substrate. For example, in U.S. Pat. No. 7,070,406 to A. H Jeans (hereinafter Jeans), the disclosure of which is incorporated herein by reference, shows an embossing apparatus comprising a flexible substrate, embossing belt, transport rollers, drive unit, backing drum, light source and coater for implementing a roll-to-roll soft lithography process that utilizes an optically transparent compliant media that carries an optically transparent imprint stamp having an imprint pattern that is formed by a grouping of sequential batch preparation steps, wherein the apparatus provides a means for embossing the imprint pattern in a photopolymer coated on an opaque flexible substrate, and, further, wherein the pattern embossed from the compliant media into the coating on the flexible substrate is cured by ultraviolet light that irradiates the pattern through the optically transparent media and imprint stamp contemporaneously with the embossing.

In the embossing apparatus of Jeans, the desired imprint pattern is cured in an elastomer layer, such as silicone-based elastomer (i.e. polydimethyl siloxane (PDMS), Dow Corning Sylgard® silicone elastomers, etc.), which is in turn coated onto a master, such as a silicon (Si) wafer. The master (i.e. the father master) comprises one or more regions of imprint patterns that are formed by etching a resist layer on the master substrate via use of standard lithography processes. The cured elastomer layer thereby includes a complementary image of the imprint pattern for the master (i.e. which corresponds to the desired replication pattern). The imprint stamp of Jeans must be removed from the excess portion of the elastomer layer and any cover layer (release and/or planarization layer) material that surrounds the imprint stamp. Stamp removal is accomplished by placing the elastomer layer on a flat surface or a substrate (i.e. plate of glass, metal, quartz, etc.) and cutting around a perimeter of the imprint stamp to remove excess portions therefrom. While the disclosed embossing apparatus of Jeans requires steps be carried out that can be repeated, as necessary, to produce additional imprint stamps from the otherwise undamaged father master, Jeans requires multiple, highly tedious, batch process steps be undertaken in order to produce and subsequently use an imprint stamp or multiple imprint stamps from the father master.

For example, Jean further discloses coating a photopolymer solution (i.e. mixture of photopolymer, such as Norland™ Optical Adhesive, and solvent, such as acetone at 50% solids) with thickness of about 5 to 10 microns onto a thin plastic film, such as polyethylene terephthalate, which has been placed on a flat compliant silicone rubber backing layer having a thickness in the range of approximately 0.125 to 0.25 inches. The imprint stamp, constructed as set forth above, is then progressively lowered into contact with the photopolymer layer so as to displace any entrapped air bubbles. It is important that the imprint stamp be precisely positioned on the photopolymer layer, such as by floating the imprint stamp on the photopolymer layer, before the photopolymer layer is cured with ultraviolet light (e.g. light of a wavelength between about 300 nm and 400 nm). In this manner, the image of the imprint stamp is accurately transferred onto the photopolymer layer before the subsequent curing process. After the photopolymer layer is cured and hardened, the imprint stamp is then removed from the photopolymer layer, resulting in the complementary pattern of the imprint stamp being fixed in the surface of the cured photopolymer layer.

This complementary pattern, which represents the feature pattern of the father master, is then post cured with heat to facilitate removal of the imprinted photopolymer layer from the rubber backing layer. The imprinted photopolymer layer on the plastic film can therefore be subsequently attached to a support substrate, such as glass or quartz, using an adhesive, such as a high temperature adhesive tape.

In Jean, the imprinted photopolymer layer, which is adhered to a thin polymer film, is then coated again with a compliant material, such as the aforementioned silicone-based elastomer material(s). The compliant material is additionally coated onto any shims that are positioned to the side of the support substrate for the imprinted photopolymer layer, the shims being preferably taller than the thickness of the imprinted photopolymer layer. The imprint pattern in the photopolymer film, which in turn is adhered to the thin polymer film, is thereby further transferred to the coated compliant material. However, additional steps are still required to complete preparation of the resultant imprint stamp for the disclosed replication apparatus. Specifically, the compliant material coated on the imprinted photopolymer layer requires heating, which is achieved through the application of heat onto the support substrate. This application of heat cures the compliant material and, after a suitable cooling period, the shims must then be removed from the support substrate by cutting the cured compliant material along the periphery of each shim. Thereafter, a thin transfer adhesive layer, preferably in the form of an optically transparent material, is applied to the surface of the heat cured compliant material. More specifically, a first adhesive surface for the adhesive layer is exposed (e.g. by removing its backing layer) and in turn applied onto the surface of the cured compliant material. Then, a rubber roller is used to progressively apply the first adhesive surface of the transfer adhesive layer across the entire surface of the heat cured compliant material.

The resultant multilayered film structure, which includes a transfer adhesive layer, a cured compliant material layer, an imprinted photopolymer layer and a thin polymer film, is then removed as a monolithic multilayered film structure from the support substrate and, in turn, laminated onto the surface of an optically transparent cylinder in alignment therewith. Lamination occurs by removing the second backing layer of the outer adhesive transfer layer and progressively applying the exposed adhesive surface to the outer surface of the aligned, optically transparent cylinder (e.g. by rolling the cylinder against the multilayered film structure.

In Jean, a gap is created between the adjacent ends of the compliant film structure that has been applied to the optically transparent cylinder. Furthermore, an excess portion of the compliant film structure may require trimming so that the gap between adjacent ends of the compliant assembly is as minimal as practicable. However, Jean does not disclose any teachings for ensuring that the compliant film structure be a continuous layer about the outer surface of the optically transparent cylinder (i.e. without a gap between adjacent ends). Instead, as a final step, Jean teaches removing the dual-layer structure of the imprinted photopolymer layer and the attached thin polymer film from the cured compliant material layer. As such, the imprint features in the surface of the compliant material layer are exposed for use in contact copying applications (e.g. through direct contact with a layer of a photopolymer material, such as a roll of photopolymer film).

Prior art (e.g. Jeans and U.S. Pat. No. 8,027,086 to L. J. Gao et al.,) illustrate the current state of the art in producing a cylindrical, or drum-like, NIL master with micron or nanoscale features. In particular, although micron or nanoscale features can written into paper or cardboard printing gravure rolls through the use of a diamond scribe or laser machining, similar techniques are not typically utilized to create such features in cylindrical NIL masters.

Once manufactured, a master produced through multiple lithographic and etching steps is then used as a father master. To replicate the feature pattern on the father master, a seed layer of conductive material is deposited thereon. More specifically, a metal, usually nickel, is electroplated onto the father master and subsequently removed therefrom, the resultant metal product being commonly referred to in the art as a daughter master or “shim”. Multiple metal shims are then combined through laser welding to form a continuous sleeve, which may have many imperfections, such as discontinuities and weld protrusions. A nickel sleeve, as constructed above, is especially well suited for hot embossing or for UV nanoimprint lithography. Producing the father master, however, involves time-consuming and expensive batch processes and is difficult to accomplish in an accurate fashion.

In the alternative, a daughter mask may be produced through sequence of batch process steps, such as of the type summarized above. Such batch process steps for forming the daughter mask include coating the “father” master with a compliant liquid polymer elastomer, such as PDMS (Polydimethylsiloxane) or Dow Corning Sylgard® silicone elastomers. Thereafter, the feature pattern of the father master is imprinted into the compliant polymerizable material and subsequently baked or otherwise cured, such as by irradiation with ultraviolet light. As a result, the compliant material is hardened with a first complementary imprint image of the feature pattern fixed therein. The compliant elastomer layer is then peeled, lifted off, or otherwise separated from the original wafer or quartz father master as a flexible sheet or film. The compliant elastomer layer, with the complementary imprint image fixed therein, then, by way of example, transferred and attached to another substrate. The aforementioned process repeats to form multiple daughter masters from a common father master. In other words, additional layers of compliant or polymerizable material are coated onto the father master and subsequently hardened, such as by baking or irradiation with ultraviolet radiation, to transfer the feature pattern in the first compliant material onto the second compliant material.

Once separated from the first compliant or polymerizable material, the opposing surface of the second hardened compliant material is wrapped around the outer surface of a drum and is attached thereto, such as by using a double-sided transfer adhesive layer and/or a mechanical holding means, such as clamps. In the alternative, with the first and second compliant materials still coupled together, a first adhesive side of a double-sided transfer adhesive can be applied to the opposing surface of the second hardened compliant material surface (i.e. the surface that does not have the imprinted pattern). Then, the second adhesive side of the transfer adhesive is exposed and thereby used to progressively apply and attach the opposing surface of the second hardened compliant material to the drum. Thereafter, the first hardened compliant material is separated from the second hardened compliant material, the exposed surface of the second hardened complaint material thus serving as the outermost surface of the drum, which can then be used for replicating the feature pattern through contact copying methods.

Daughter masks produced in the manner set forth above suffer from a notable shortcoming. Namely, daughter masks of this type are not completely continuous about the drum on which it is mounted. Consequently, a gap or mismatch error is created between adjacent ends of the daughter mask once attached to the surface of the drum. The presence of such a gap causes problems when the daughter mask is used in contact copying (i.e. feature pattern replication). Specifically, the gap creates a repeating seam in the copied medium when carried out using a roll-to-roll process. Due to the presence of such seams, additional steps are often required to treat the copied medium. For example, the roll into which the imprint pattern is copied from the daughter mask is often carefully cut or sectioned to remove such seams. As another example, when multiple passes are made in a roll-to-roll process (i.e. to create multilayered structures) complex procedures for aligning the copied medium are required. As the feature size of flexible electronics manufactured through contact copying decreases, compensation for gap-related issues has become an increasingly challenging problem. As a result, it has been found that semiconductor mask fabrication is only proficient at producing features on flat substrates.

### SUMMARY OF THE INVENTION

The present invention is an apparatus and method for (i) producing a seamless continuous cylindrical surface-relief patterned mask(s) comprising microscale and/or nanoscale features for use in roll-to-roll or long panel nanoimprint lithography or reverse nanoimprint lithography, and (ii) contact copying or replication for replicating or imprinting microscale or nanoscale features from the seamless continuous cylindrical surface-relief patterned mask into a photopolymerizable material, photopolymer resist or thermoplastic material.

In one embodiment the apparatus and method of the present invention comprises a mount assembly for mounting or attaching a master, for example, a flat master, wherein the mounted master has on its outer major surface the master surface-relief features or pattern that is to be imprinted or otherwise transferred to a cylindrical daughter master which can be used for nanoimprint lithography or contact copying or replication applications or processes.

In another aspect of the apparatus of the present invention, the apparatus provides a means for translation motion along a axis in a first direction that is parallel to the surface of the mounted master, wherein the mount holding the master, by way of example, without limitation, can be a vacuum chuck having an extremely flat major surface to which a holding vacuum is applied to one or more locations or areas of its flat major surface thereby providing a means of holding the master to the contacting surface of the mount, where the master can, for example, be a silicon wafer which may be bowed or “potato chipped” but have parallel opposing surfaces that are pulled substantially flat by the holding vacuum so as to uniformly contact and be held on the flat major surface of the mount, and wherein the extremely flat major surface of the mount holding the master is oriented to be substantially parallel to the plane containing the first direction of the said translation motion.

In another aspect, the continuous cylindrical surface-relief patterned mask of the apparatus and method that is used to copy or replicate from the cylindrical surface-relief patterned mask into the surface of a copy media, such as a photopolymerizable material, photopolymer resist or thermoplastic material, is made on the surface of a cylinder, which may be an optically transparent cylinder that is transmissive to actinic radiation, such as light of ultraviolet wavelengths, wherein the diameter of the cylinder is particularly selected such that its circumference is nearly exactly the length of the pattern on the mounted master that is to be replicated in a continuous manner, and, further, wherein the cylinder is mounted to a second motion axis that operates as a rotation axis oriented perpendicular to the first motion axis used for translation of the mounted master along a first direction that is parallel to the plane containing the surface of the mounted master, wherein the resolution of the linear translation along the first motion axis for translating the mounted master is matched to the resolution of the cylinder rotation about the second motion axis for rotation of the mounted cylinder and also to the feature tolerance for the pattern on the master that is to be transferred or imprinted to the surface of the cylinder, as may be needed so as to be able to copy, imprint or replicate the microscale and/or nanoscale features into a copy media with the desired fidelity.

In another aspect, the cylindrical surface-relief patterned mask of the apparatus and method is made by a means which transfers or imprints the master surface-relief microscale and/or nanoscale features or pattern to the cylindrical surface of the cylinder without there being a gap between the opposing edges of the pattern that is transferred or imprinted from the pattern of the mounted master.

In another aspect, the apparatus and method of the present invention includes a third axis of motion that is oriented to be orthogonal to the first axis of motion for the translation axis of the mounted master and to the second axis of motion for rotating the mounted cylinder, so as to provide a means for adjusting and setting the dimension of the gap between the master and the cylinder such that it can be set at an appropriate dimension or target force for producing the cylindrical surface-relief patterned mask of the apparatus.

In another aspect, the apparatus and method of the present invention further includes a fourth axis of motion which is a rotational axis about which the mount for holding the master, for example, a vacuum chuck to which a holding vacuum is applied to one or more locations or areas of its flat major surface thereby providing a means of holding the master to the contacting surface of the mount, can be rotated to provide a means of aligning the master's pattern of microscale or nanoscale features so the set of features can be set square or otherwise suitably aligned with respect to the direction of the first motion axis for translating the mounted master, wherein such alignment can be assisted and/or determined by the presence of fiducials that may be positioned within the master pattern of microscale or nanoscale features, or at one or more edges of the master pattern of microscale or nanoscale features, or combinations thereof.

In another aspect, the apparatus and method of the present invention includes a light source for polymerizing and/or curing prepolymers at the surface of the cylinder on which is formed the continuous cylindrical surface-relief patterned mask, and additionally for polymerizing and/or curing prepolymers at the surface of the roll-to-roll coating into which the seamless continuous cylindrical surface-relief pattern is transferred or imprinted, such as by way of contact copying, for purposes of fixing the transferred or imprinted pattern as may be needed, wherein the light source preferably emits actinic radiation of ultraviolet wavelengths, which, by way of example, without limitation can be a light source that is fabricated utilizing one or more high intensity light emitting diodes (LEDs), such as Luminus Devices CBT120 LEDs, or laser diodes or other suitable lighting means.

In another aspect, the light source of the apparatus and method of the present invention is imaged with one or more optical elements onto the surface of the cylinder of the apparatus so as to provide the desired wavefront and intensity to produce the seamless continuous cylindrical surface-relief pattern mask, wherein the imaging optics can include, by way of example, a cylindrical lens made from quartz or fused silica or an acrylate, methacrylate or cyclic olefin copolymer or other suitable material, and, optionally, one or more mirrors can be affixed to the ends of the said cylindrical lens to provide a means for reflecting the light thereby creating a cavity and effectively an infinite light source in one dimension.

In another aspect, the light source of the apparatus and method emits a diverging wavefront, such as from a LED source, and is controllably positioned to be at a location just beyond the distance corresponding to the finite conjugate plane for the focal point of the optical element, for example a cylindrical lens, so the optical element can produce a sharp image at the surface location on the cylinder where the continuous cylindrical surface-relief pattern mask is to be made. Alternatively, the light source is positioned at the finite conjugate plane for the focal point of the optical element and the cylinder into which the continuous cylindrical surface-relief pattern mask is to be made is controllably positioned so that its surface on which the continuous cylindrical surface-relief pattern mask is to be made is disposed at a location enough beyond the distance corresponding to the finite conjugate plane for the focal point of the optical element that the optical element can produce a sharp image at the said surface location on the cylinder where the continuous cylindrical surface-relief pattern mask is to be made. Further, the said distance over which the propagating wavefront having converging power passes through an appropriate air gap distance between the optical element and the first encountered surface of the cylinder of the apparatus used to produce the seamless continuous cylindrical surface-relief pattern mask, takes into consideration refraction of the converging optical wavefront due to it entering the cylinder material and passing through a diameter thickness of the material, which can be made from a material of suitably low refractive index, before the converging wavefront focuses at the opposing surface of the cylinder where the seamless continuous cylindrical surface-relief pattern mask is to be produced. The image of the light source on the surface of the cylinder on which the continuous cylindrical surface-relief pattern mask is to be made can be a line image of the light source when the optical element is a cylindrical lens, for example, a line image of a grouping of LED or laser diode light sources, wherein the width of the line image is preferably about the width of the light source.

In another aspect of the apparatus and method of the present invention, the apparatus may optionally include a turning (cutting) tool, such as a single point diamond mounted on the transverse axis of the mounted cylinder, so that the surface of the cylinder for the cylindrical surface-relief patterned mask may be turned to have nearly the exact diameter and resulting circumference so as to match the length of the pattern on the mounted master, such that one rotation of the cylinder equals the length of the desired pattern that is to be imprinted from the master to the cylindrical surface.

In another aspect, the outer surface of the mounted master of the apparatus of the present invention can, by way of example, be silicon, fused silica, or can be nickel or other suitable metal that can additionally be coated with at least a molecular thickness of a release agent, which, for example, can be Gelest PP1-AQCM-Aquaphobe-CF-TDS or other suitable release agent.

In another aspect, the optically transparent cylinder of the apparatus can be made from a material such as quartz, fused silica or UVT acrylic made by Polyone Inc. which is transmissive to 320 nm ultraviolet light, or other optically clear polymer material that can be a semi-crystalline or an amorphous polymer, such as a thermoplastic polymer or a polymer resin, for example, an acrylate or methacrylate, such as poly(methyl methacrylate), or a poly(aryletherketone) such as polyether ether ketone or polyetherketoneketone, or a polyvinyl butyral such as Butvar®, or an aliphatic polyurethane resin, an epoxy resin, a polyester resin, or a cyclic olefin copolymer such as TOPAS®, or an ethylene-tetrafluroethylene copolymer such as Tefzel®, or it may be one of the foregoing materials additionally comprising a coated compliant surface layer of suitable thickness.

In another aspect, the rotational axis of the cylinder on which is produced the cylindrical surface-relief patterned mask of the apparatus and method, is driven or controlled by a direct drive motor equipped, by way of example, without limitation, with an absolute optical encoder capability having extreme rotational resolution and precision, for example, a Renishaw Resolute™ encoder that provides 30 bit or 26 bit rotational resolution corresponding to 1,073,741,824 counts per revolution and 67,108,864 counts per revolution, respectively.

Other aspects and advantages of the present invention will become apparent from the following detailed description taken in conjunction with the referenced and accompanying figures, which illustrates by way of example principles of the present invention.

### BRIEF DESCRIPTION OF THE DRAWINGS

In the drawings wherein like reference numerals represent like parts:

FIG. 1 is a simplified schematic representation of a novel system for manufacturing a cylindrical, nanoimprint lithography (NIL) master, the system being constructed according to the teachings of the present invention;

FIG. 2 is a detailed implementation of an apparatus for manufacturing a cylindrical NIL master, the apparatus including the principal components of the system shown in FIG. 1;

FIG. 3 is a detailed implementation of a roll-to-roll nanoimprint lithography apparatus, the apparatus incorporating selected components of the master manufacturing apparatus shown in FIG. 2; and

FIG. 4 is an enlarged, front view of the father master and daughter master shown in FIG. 2, the view being useful in illustrating the high-speed imprinting and curing process of the present invention.

### DETAILED DESCRIPTION OF THE INVENTION

### Cylindrical NIL Master Manufacturing System 11

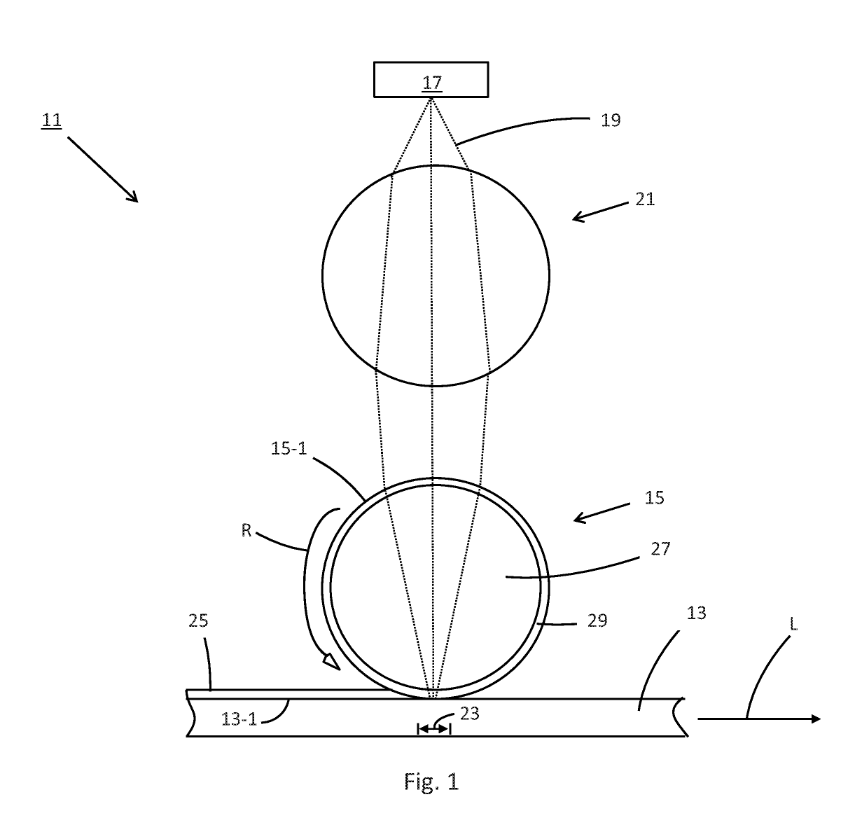

Referring now to FIG. 1, there is shown a novel system for manufacturing a cylindrical, nanoimprint lithography (NIL) master, the system being constructed according to the teachings of the present invention and identified generally by reference numeral 11. As will be described in detail below, system 11 is designed to pattern nanoscale features onto the outer surface of a cylindrical master without creating a seam (i.e. mismatch) in the patterned exterior surface, which is a principal object of the present invention.

As can be seen, system 11 comprises (i) a generally flat master 13 having an externally patterned surface 13-1, (ii) a cylindrical, or roller-type, master 15 disposed in continuous, compressive, tangential contact with patterned surface 13-1, (iii) a light source 17 for producing light 19, and (iv) an optical element 21 for directing light 19 from light source 17 into cylindrical master 15. As will be explained further below, the feature pattern in surface 13-1 is transferred onto exterior surface 15-1 of cylindrical master 15 using a light-activated resin that is coated onto at least one of surfaces 13-1 and 15-1. The photopolymer material is then cured by light 19 generated from source 17 which is, in turn, focused by optical element 21 and cylindrical master 15 into a narrow curing zone within the region of contact 23 between flat master 13 and cylindrical master 15.

Flat master 13 represents any generally flat stamp, disc or plate which includes an external surface patterned with nanoscale features through any suitable high precision patterning technique, such as electron beam lithography, focused ion beam milling, dry etching and the like. As part of the manufacturing process, a single flat master 13 can be reused to pattern a large quantity of cylindrical masters 15. For this reason, flat master 13 is also referred to herein simply as a “father” master, whereas cylindrical master 15 is also referred to herein simply as a “daughter” master.

For reasons to become apparent below, flat master 13 is adapted to travel along a linear path L which extends in parallel with the planar region of contact 23 between flat master 13 and cylindrical master 15. Furthermore, it should be noted that patterned surface 13-1 on flat master 13 has a length that is equal to the circumference of cylindrical master 15. Accordingly, through acute synchronization of the translational displacement of flat master 13 and rotational displacement of cylindrical master 15, a seamless pattern transfer can occur between father master 13 and daughter master 15.

In the present embodiment, patterned surface 13-1 of flat master 13 is shown coated with a photopolymer material 25 with viscoelastic properties, such as polydimethylsiloxane (PDMS). Due to its compliant nature, the pressure applied from cylindrical master 15 onto flat master 13 causes material, or coating, 25 to compress, or deform, within region of contact 23 to a considerable degree. More particularly, pressure is applied such that material 25 exhibits compressive strain in the range from approximately 5% to approximately 20%. As can be appreciated, the compliance of material 25 not only compensates for gap tolerances between masters 13 and 15 but also expands, or widens, region of contact 23, which is essential in providing adequate time for curing of material 25 during the relatively high-speed pattern transfer bonding process, as will be explained further below.

Roller-type master 15 is represented herein as a unitary element comprising an optically transparent axle 27 on which a compliant outer sleeve 29 is axially mounted. As referenced briefly above, master 15 is adapted for displacement along a rotational path R. In this capacity, cylindrical master 15 is can be patterned by father master 13 in a high-speed, continuous manner, which is highly desirable. Additionally, once externally patterned, cylindrical master 15 can then be used in roller-type nanoimprint lithography applications to imprint the feature pattern onto a continuous, web-type replication medium.

Outer sleeve 29 is preferably formed of a photopolymer material with viscoelastic properties, such as polydimethylsiloxane (PDMS). By utilizing the same compliant, photocurable material for sleeve 29 and coating 25, enhanced bonding is capable, which in turn facilitates pattern transfer from father master 13 to daughter master 15. However, as referenced above, it is to be understood that a single layer of compliant, photocurable material could be applied to either flat master 13 or cylindrical master 15 without departing from the spirit of the present invention.

As a feature of the present invention, cylindrical master 15 is preferably disposed in contact with flat master 13 under such pressure that the degree of compressive strain in the compliant material for sleeve 29 and coating 25 is slightly less than or equal to its maximum reversible compressive strain. As previously referenced, the deformation of the material for sleeve 29 and coating is considerable (resulting in compressive strain in the range from approximately 5% to approximately 20%), which in turn creates an extended region of contact 23 therebetween that is required to achieve effective pattern transfer at relatively high speeds.

Light source 17 represents any suitable source for emitting light 19 capable of curing the light-activated material of coating 25 and sleeve 29. As can be seen, optical element 21 and transparent axle 27 direct light 19 emitted from light source 17 into a focused curing zone within region of contact 23. In this manner, the feature pattern in surface 13-1 is effectively transferred into coating 25 through region of contact 23 and subsequently cured by focused light 19. The substantial pressure established between coating 25 and sleeve 29, as well as the aforementioned curing process, facilitates bonding of coating 25 onto sleeve 29. As a result, the feature pattern in coating 25 is permanently bonded onto the exterior of sleeve 29 towards the tail end of contact region 23. Accordingly, through both (i) geometric matching of the circumference of cylindrical master 15 against the length of the feature pattern in surface 13-1 of flat master 13 and (ii) acute synchronization of the rotational motion of cylindrical master 15 against the translational motion of flat master 13, daughter master 15 can be patterned with the feature pattern on a father master 13 in a seamless fashion (i.e. with high-precision matching between the leading edge and the trailing edge of the feature pattern on cylindrical master 15).

### Detailed Implementation of an Cylindrical NIL Master Manufacturing Apparatus 100

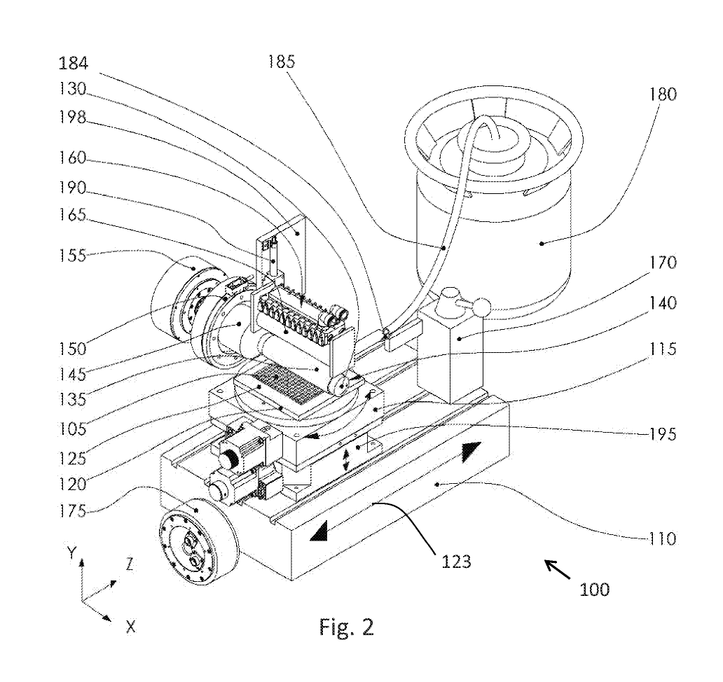

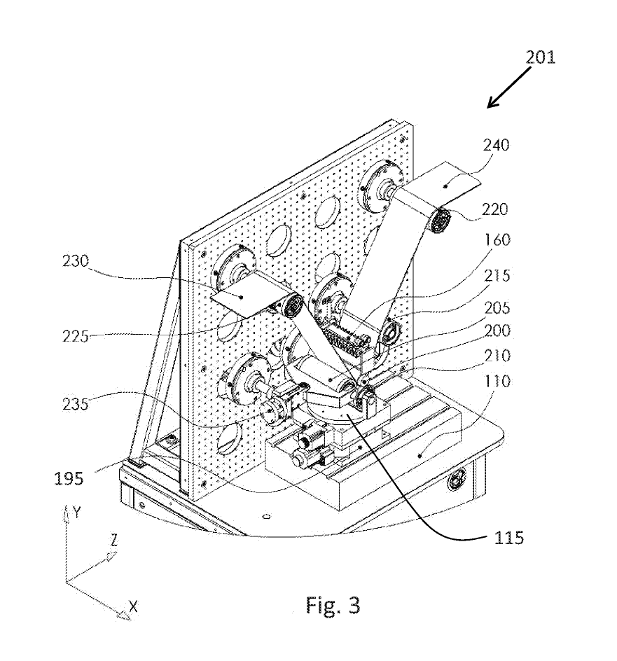

FIG. 2 represents a detailed implementation of an apparatus which includes the novel arrangement of components set forth in system 11, the apparatus being identified generally by reference numeral 100. As will be explained further below, apparatus 100 is capable of producing a seamless continuous cylindrical surface-relief patterned mask(s) with microscale and/or nanoscale features. Once patterned, the cylindrical mask can be used in roll-to-roll or long panel nanoimprint or reverse nanoimprint lithography. For example, in FIG. 3, apparatus 100 is shown slightly modified, with certain additional components, for use in contact replication of the microscale or nanoscale features from the produced, seamless, continuous, cylindrical, surface-relief patterned mask into a photopolymerizable material, photopolymer resist or thermoplastic material.

The apparatus 100 depicted schematically in FIG. 2 comprises an example master 105 and a mount assembly 120 for retaining master 105 in apparatus 100, example master 105 being shown as a flat master comprising on its top shown major surface 125 a grouping of microscale and/or nanoscale surface-relief features corresponding to the desired master surface-relief pattern that is to be imprinted or otherwise transferred onto a cylindrical daughter master 135.

The translational position of mount assembly 120 is controlled by support, or base, element 110. In use, element 110 controls translational movement of mount assembly 120 along an axis in a first direction 123 that is along the z-axis and in parallel with the surface of the mounted master 105, which is in the x-z plane. By way of example and without limitation, mounting assembly 120 may be in the form of a vacuum chuck having an extremely flat major surface 125. In turn, a holding vacuum (not shown) applies a vacuum force at one or more locations or areas of flat major surface 125, thereby providing a means of retaining master 105 onto contacting surface 125 of mount assembly 120. As a result, master 105 can, for example, be made from a silicon wafer which may be bowed or “potato chipped” but have parallel opposing surfaces that are pulled substantially flat by the holding vacuum, the bottom surface being drawn into uniform contact with flat major surface 125 of mount 120. Consequently, master 105, which is mounted on extremely flat major surface 125 of mount 120, is oriented to be substantially parallel to the plane defined by the translation path provided by component 110 (i.e. first direction 123).

Cylindrical daughter master 135 is represented herein as a continuous, cylindrical, surface-relief patterned mask (feature details not depicted) that, in turn, can be used to copy or replicate the feature pattern into the surface 255 of a copy media 250, as depicted in the FIG. 3, copy media 250 desirably being a photopolymerizable material, photopolymer resist or thermoplastic material. Continuous, cylindrical, surface-relief patterned mask 135 is made on the surface of a cylinder element 140, which may be an optically transparent cylinder that is transmissive to actinic radiation, such as light of ultraviolet wavelengths. The diameter 142 of cylinder element 140 is particularly selected such that its circumference is nearly exactly the length of master surface-relief pattern 112 on top surface 125 of mounted master 105.

Cylinder element 140 is mounted to rotatable element 145, thereby enabling cylinder element 140 to be rotatable about a second controlled motion axis 130 that is disposed along the x-direction and perpendicular to first direction 123. The resolution of the linear translation of mounted master 105 along first motion axis 123 is ideally matched to the resolution of the rotation of cylinder element 140 about second motion axis 130 as well as to the feature tolerance for the master surface-relief pattern 112 that is required to be transferred or imprinted to the surface of cylinder 140 with the desired fidelity.

Cylinder 140 is preferably rotationally driven about axis 130 by a direct drive motor 155 that is equipped with an absolute optical encoder 150 with extreme rotational resolution and precision. For example, optical encoder 150 may be in the form of a Renishaw Resolute™ encoder that provides 30-bit or 26-bit rotational resolution, which corresponds to 1,073,741,824 counts per revolution, or 67,108,864 counts per revolution, respectively. Optical encoding at the aforementioned resolutions would provide circumferential sub-nanometer resolution along the surface of cylinder 140 for the sample cylinder diameters listed in Table 1 below:

TABLE 1

| | | BITS | |
|---|---|---|---|
| | | 30 | 26 |
| Encoder | Counts/Rev | 1,073,741,824 | 67,108,864 |
| Resolution | | | |
| | Cylinder Diameter | Rotary | Rotary |
| | (mm) | Resolution (nm) | Resolution (nm) |
| | 25.4 | 0.074 | 1.19 |
| | 50.8 | 0.149 | 2.38 |
| | 76.2 | 0.223 | 3.57 |
| | 152.4 | 0.446 | 7.13 |

A vertical stage element 195 provides a third axis of controlled motion in apparatus 100 that is generally orthogonal to both first direction 123 (i.e. in the z-direction) and second axis 130 (i.e. in the x-axis). More specifically, stage element 195 provides a means for adjusting and setting the dimension of a gap along the y-direction between mounted master 105 and the major surface of cylinder 140. As such, master 105 can be set relative to cylinder 140 at an appropriate dimensional distance to achieve a target, or ideal, pressure force between mounted master 105 and the surface of cylinder 140 that facilitates the contacting or filling of the features in the master surface-relief pattern 112 by the liquid polymer precursor coated on the surface of cylinder 140.

A rotary stage element 115 provides a fourth axis of controlled motion in apparatus 100 that rotates about the y-axis. As shown herein, mounted master 105 is held on rotary control element 115, by, for example, a vacuum chuck. In this manner, mounted master 105 can be controllably rotated to provide a means of aligning the master surface-relief pattern 112 on father master 105 with cylindrical daughter master 135. As such, master 105 can be set square to or otherwise suitably aligned with first direction 123 (i.e. along the z-axis) and/or optionally aligned with master surface-relief pattern 112. Such rotary alignment of master surface-relief pattern 112 can be assisted and/or determined by use of fiducial features and/or markings that may be positioned within and/or along the outer edges of master surface-relief pattern 112.

The continuous, cylindrical, surface-relief patterned mask 135 is produced using a replicating medium coated on the major surface of cylinder 140. The replicating medium is preferably a material that can be suitably imprinted with master surface-relief pattern 112, such as by use of photopolymerization and curing methods that preferably use actinic light of ultraviolet wavelengths to illuminate and thereby expose the desired regions in the coating layer so as to fix the imprinted pattern from master surface-relief pattern 112. Heat-based curing methods may also be used to fix the imprinted pattern from master surface-relief pattern 112 onto mask 135 (e.g. by heating cylinder 140 and its major surface).

Cylinder 140 is preferably optically transparent and may be made from a material such as Fused Silica, Fused Quartz, or UVT acrylic made by Polyone Inc. (which is transmissive to 320 nm ultraviolet light). Other optically clear polymer materials that can used to form cylinder 140 include a semi-crystalline or an amorphous polymer, such as a thermoplastic polymer or a polymer resin (e.g. an acrylate or methacrylate, such as poly(methyl methacrylate), or a poly(aryletherketone) such as polyether ether ketone or polyetherketoneketone, or a polyvinyl butyral such as Butvar®, or an aliphatic polyurethane resin, an epoxy resin, a polyester resin, or a cyclic olefin copolymer such as TOPAS®, or an ethylene-tetrafluroethylene copolymer such as Tefzel®), or it may be one of the foregoing materials additionally comprising a coated compliant surface layer of suitable thickness.

Examples of a photocurable replicating medium that can be coated on the major surface of cylinder 140 or master surface-relief pattern 112 include, but are not limited to, Shin-Etsu Chemical PDMS KER-4690 liquid silicon rubber that has a low coefficient of linear contraction and low surface energy, Micro Resist Technology GmbH mr-XNIL26 and mr-UVCur26SF coating materials, and the like, which can be photopolymerized by exposing the medium to light having ultraviolet wavelengths. The first example medium requires an exposure irradiance of about 1 joule/cm² to be cured, whereas other known photopolymerizable materials can be used in place thereof which can be cured with actinic radiation at lower levels of exposure irradiance. Other examples of a replicating medium that may be suitable for imprinting the microscale and/or nanoscale features from the cylindrical surface-relief patterned mask 135 may include compliant liquid prepolymer elastomers, such as silicon elastomer materials disclosed by Jeans or Guo et al., and can generally be selected based on various desirable parameters, including, but not limited to, the chemical, mechanical, thermal and optical properties of the material, including its surface energy, glass transition temperature, Young's modulus, transparency, solvent resistance, exposure energy and intensity required for achieving suitable extent of polymerization. Specific desirable properties may additionally include the chemical and mechanical durability of mask 135 to sustained light exposure that is required during its subsequent use in contact copying or replication (e.g. in apparatus 200).

The surface of the mounted master 105 and/or the surface of cylinder 140 is preferably pre-coated with a replicating medium suitable for imprinting master surface-relief pattern 112 into the medium with the desired fidelity. As part of the initial setup of apparatus 100, mounted master 105 is positioned directly beneath cylinder 140 in proper alignment and orientation therewith such that master surface-relief pattern 112 is loaded with the desired amount of pressure on the replicating medium that, for example, is coated on the major surface of cylinder 140. The coated replicating medium can thereby be loaded with a sufficient pressure, if needed, so as to completely fill and cover the microscale and/or nanoscale features of master surface-relief pattern 112, and, additionally, to facilitate suitable bonding of the cured replicating medium to the surface of cylinder 140 when the cylindrical surface-relief patterned mask 135 is formed. As referenced briefly above, bonding of the cured replicating medium to cylinder 140 may be further enhanced, if needed, by heating cylinder 140.

Apparatus 100 of the present invention includes a light source 160 for (i) polymerizing and/or curing prepolymers coated on the surface of the cylinder 140 (i.e. during the manufacture of cylinder 140) and (ii) polymerizing and/or curing prepolymers at the surface of a roll-to-roll coating into which the seamless continuous cylindrical surface-relief pattern 135 is transferred or imprinted (i.e. during roll-to-roll NIL fabrication processes). By way of example, light source 160 may be formed using one or more high intensity light emitting diodes (LEDs), such as Luminus Devices CBT120 LEDs, laser diodes, or other suitable lighting means. Readily-available UV emitting Mercury lamps or LED lamps do not generally serve as an adequate light source that provides the exposure conditions needed for the photopolymerization or curing of the replicating medium used to produce the desired, continuous, cylindrical, surface-relief patterned mask 135.

As represented herein, light source 160 is disposed in a fixture that is positioned above cylinder 135 and is designed to emit light of ultraviolet wavelengths. For example, light source 160 may be fabricated by using one or more high-intensity light emitting diodes (e.g. a laser diode or the Luminus Devices CBT120 LED), which are disposed or arranged, inter alia, as a 1-dimensional array along the direction of the x-axis or as a 2-dimensional array within x-z plane, the 2-dimensional array including two or more rows of LEDs, each oriented along the x-axis, which optionally may be staggered with respect to their absolute positions along the z-axis, or arranged in other suitable configurations as may be needed.

Light source 160 can be imaged onto the surface of cylinder 140 using an optical element 165, thereby providing the desired wavefront and intensity required to produce mask 135. Optical element 165 can include, by way of example, at least a cylindrical lens element made from fused silica, quartz, or an acrylate, methacrylate or cyclic olefin copolymer or other suitable optically transparent material. Optionally, optical element 165 can have one or more mirrors or mirrored surfaces at its ends so as to provide an additional means for reflecting and/or collecting a portion of the light propagated from light source 160, thereby creating a cavity and effectively an infinite light source in one dimension.

As shown herein, light diverging from a 1-Dimensional array of high output LEDs can be imaged onto the surface of target cylinder 140 with use of imaging optics element 165. Optionally, imaging optics element 165 may comprise an arrangement of microlens elements, such as a 1-dimensional or a 2-dimensional microlens array, wherein each microlens in the array has a selected cylindrical optical power along a desirable axis or other suitable optical power. Still further, imaging optics element 165 may comprise a first optical element that focuses the diverging wavefront emitted from the high output LEDs and a second optical element, separate from the first optical element, having optical power by a distance equal to the sum of the focal lengths of the two optical elements. Still further, if the two optical elements are, for example, each a cylindrical lens oriented with its respective cylindrical optical axis perpendicular to the other, then the resulting modified wavefront can be desirably shaped by a third lens element, such as singlet or doublet lens of desirable diameter and focal length. The resultant output profile is a collimated rectangular bar of light having a defined length and width which is exposed onto cylinder 140 at the desired location for the curing zone.

In another embodiment, when light source 160 emits light from one or more LED light source elements so as to produce a diverging wavefront of finite distance, then the location of the LED light source is desirably and controllably positioned in apparatus 100 beyond the distance for the location of the finite conjugate plane of imaging optics element 165. As a result, the sharpest imaging of LED light source 160 onto the desired curing location on the surface of cylinder 140 is achieved. Alternatively, an LED light source emitting a diverging wavefront may be positioned at a distance from imaging optics element 165 that directly corresponds to the focal length of imaging optics element 165, with the distance between imaging optics element 165 and the surface of cylinder 140 being controllably adjusted beyond the distance of the finite conjugate plane of imaging optics element 165, again to achieve the sharpest imaging of LED light source 160 onto the surface of the cylinder 140 where the cylindrical surface-relief patterned mask 135 is to be imprinted from surface-relief pattern 112.

### Method of Pattern Imprinting

In apparatus 100, the wavefront propagating from imaging optics element 165 enters cylinder 140 and is refracted by its optically transparent material so as to impinge on the opposing outer surface of cylinder 140 (i.e. where cylindrical surface-relief patterned mask 135 is to be imprinted from surface-relief pattern 112). For example, in FIG. 1, light source 17 is separated a first distance from a cylindrical imaging optical element 21. In turn, cylinder 15 on which the patterned mask is to be produced, is separated by a second distance from imaging optical element 21.

The ray tracing shown in FIG. 1 shows a diverging wavefront emitted from the LED light source 17 entering and exiting cylindrical optical element 21, thereby producing a converging wavefront that enters cylinder 15. In turn, the wavefront is refracted to steeper angles by the optically transparent material of cylinder 15 for its continued propagation to the opposing surface of cylinder 15. Finally, light converges, preferably to a focus, onto the opposing surface of cylinder 15 within the region of pattern transfer.

In the case of the light source 17 comprising an array of LEDs, the resulting image can desirably be a line image, wherein the width of the line image along the z-direction is preferably the width of the LED emitter source and the length of the line image along the x-direction is preferably matched to the corresponding dimension of the master surface-relief pattern 13-1 along the same direction so as to avoid irradiating the photopolymer coating material in regions outside pattern 13-1.

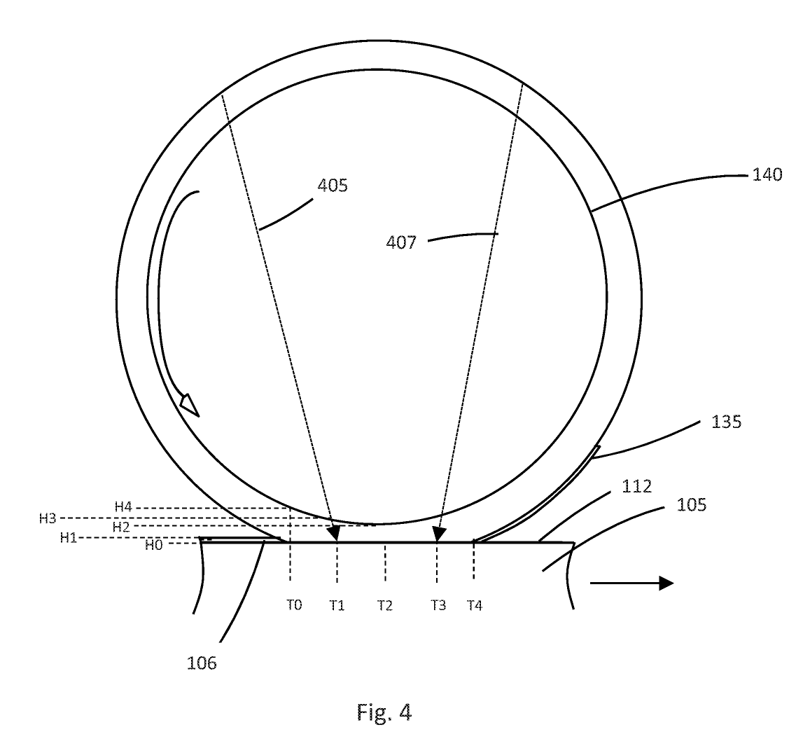

Referring now to FIG. 4, there is shown an enlarged, schematic representation of the cure and imprinting zone in apparatus 100 that is useful in illustrating the novel pattern transfer process of the present invention. As can be seen, a replicating medium 106, described above as a photopolymerizable liquid prepolymer coating material, is coated on master 105 and has a thickness equal to the depicted H1-H0. The position of master 105 is controllably adjusted in the y-direction (i.e. vertically towards cylinder 140) by vertical stage element 195 so as to dispose the outer surface of cylinder 140 from replicating medium 106 at a separation distance equal to the value depicted as H1-H0 at time T0. In other words, imprinting medium 106, having a thickness equal to H1-H0, first comes into contact with the outer surface of cylinder 140 at time T0.

Between time T0 and T1, photopolymer coating material 106 experiences compression pressure as it is squeezed between the outer surface of cylinder 140 and master surface-relief pattern 112 so as to be in intimate contact with both the imprint features of master surface-relief pattern 112 and the surface of cylinder 140. At time T1, photopolymer coating material 106 enters the curing zone, as defined by the outermost converging ray 405 of the actinic radiation propagating from light source 160 that is, in turn, focused by imaging optics element 165. Photopolymerization is thereby initiated in the photopolymer coating material 106 upon entering the curing zone, and as coating material 106 is being cured, it continues to be subjected to increasing pressure. This increased pressure forces coating material 106 to completely flow into the microscale and/or nanoscale features of master surface-relief pattern 112 that are to be imprinted. The compression pressure in the curing zone, however, is limited by several parameters including, by way of example, (i) the viscosity and compressibility of the photopolymer coating material 106, which changes as it polymerizes, (ii) the dimension of the gap width between master surface-relief pattern 112 and the outer surface of cylinder 140, and (iii) the speed of the rotational and translational motions of cylinder 140 and master 105, respectively.

At time T2, photopolymer coating material 106 experiences maximum compression as cylinder 140 and master 105 are drawn closest together (i.e. reach their smallest degree of separation). Additionally, time T2 represents the midpoint of the total curing exposure irradiance (i.e. the center of the curing zone). In response, the viscosity of photopolymer coating material 106 continues to increase in the curing zone as cross-linking and chain extension reactions occur that rapidly increase the molecular weight of the polymerizing network structure. Between time T2 and T3, the mechanical stress on the curing photopolymer material 106 decreases, changing from experiencing maximum compression at time T2 to a diminishing relaxed state of compression, as the distance between the outer surface of cylinder 140 and master 105 increases.

The curing photopolymer material 106 exits the cure zone at time T3, as represented by the outermost converging ray 407 of the actinic radiation propagating from the light source 160. However, chain extension and crosslinking reactions (generally referred to as dark reactions) continue to build molecular weight within the polymerizing network immediately after light exposure due to propagating chain growth initiated by the actinic radiation continuing as a result of diffusion of monomer to the reacting chain ends of the polymer network. The curing photopolymer material 106 thereby experiences increasing tension as it is moves beyond the cure zone (i.e. where the distance between the outer surface of cylinder 140 and master 105 continues to increase). This increased tension occurs due to anchoring adhesive forces on both opposing surfaces of curing photopolymer layer 106. Once the increasing tension exceeds the adhesive force anchoring photopolymer material 106 to master 105, the coating of cured photopolymer material 106 transfers and is anchored to the outer surface of cylinder 140, as shown at time T4 (i.e. where the depicted separation distance between cylinder 140 and master 105 is equal to H4).

After T4, where the separation distance between the outer surface of cylinder 140 and the master 105 exceeds H4, the complementary feature pattern of master 105 that is imprinted into surface of the photopolymer material 106′ becomes, in a continuous manner, the above described continuous cylindrical surface-relief patterned mask 135 on the outer surface of cylinder 140.

In order to produce patterned mask 135 with no gap between the adjacent ends of the transferred or imprinted pattern, both (i) rotational and translational synchronization and (ii) geometric matching of the complementary surfaces of master 105 and cylinder 140 are utilized. Any error in the circumference of cylinder 140 relative to the length of the linear feature pattern on master 105 creates a seam, or mismatch, upon completion of the rotation of cylinder 140 during the above described imprinting method. For example, a one percent error on a 100 mm length feature pattern with 100 nm sized features would normally result in virtually no error in the features of the imprinted feature pattern, but would create a 1 mm error at the seam between the beginning and the end of the imprinted feature pattern.

The method and apparatus of the present invention advantageously utilizes a stage resolution accurate to nanometer or sub-nanometer levels and comparable angular resolution to achieve precision matching of the feature pattern translation and the angular cylinder rotation during the imprinting process. In this manner, even with an extremely small continuous velocity error measured at the surface, there is not an accumulating mismatch. Rather, the imprinted pattern is effectively distorted uniformly by 1% during the continuous imprinting process so that there is a 1 nanometer error on each of the imprinted 100 nanometer features but there is no accumulating error that would cause a gap, or seam, between the adjacent ends of the imprinted mask 135.

In another embodiment, when a discontinuity (i.e. seam) is tolerable and local precision within the microscale or nanoscale features of the imprinted pattern is paramount, then, alternatively, the surface velocities are matched rather than synchronizing the linear velocity to angular velocity. This can be accomplished by exactly characterizing the diameter of the cylinder 140 prior to imprinting. For example, in place of master 105, top major surface 125 of mount assembly 120, which is preferably a high friction surface, can be loaded against cylinder 140 with sufficient normal force to create enough resulting friction to drive cylinder 140 about its rotary axis without slip. Cylinder 140 can then be mounted on an air bearing rotary actuator and thereby be allowed to free spin against the translating surface 125. The linear translation stage 110, with nanometer precision, can translate a predefined precise distance along the z-direction so as to minimize local errors. The cumulative rotational angle θ of the “free-wheeling” rotary axis is thereby exactly equal to the linear translation distance, L, divided by the cylinder diameter, D.

The information relating to the cumulative rotational angle can then be used in apparatus 100 during the pattern imprinting process so as to precisely drive the rotary motion of cylinder 140 to achieve an exact surface speed match rather than matching the rotational angle to the linearly translated distance. The governing relationship is thus maintained by setting (ΔθD/Δt)=(ΔL/Δt). Alternatively, the information relating to the cumulative rotational angle can be used to machine an offset in the diameter of the cylinder 140 mounted on the said rotary actuator, for example with use of a fixtured, single point, diamond turning tool 184 located at the end of a cooling delivery line 185. If needed, turning tool 184 can be cooled by a cooling gas or liquid provided from supply tank 180. Further, it should be noted that turning tool 184 is preferably mounted on a translation mounting element 170, which allows for linear movement of turning tool 195 along the z-axis direction relative to cylinder 140. In this capacity, turning tool 184 provides a means of setting the diameter 142 of cylinder 140 to be significantly closer to the desired target dimension.

In another embodiment, the imprint pattern transfer method of the present invention can initially coat cylinder 140 with a compliant material that is transmissive to actinic radiation, such as light having ultraviolet (UV) wavelengths. For example, the compliant material can be in the form of PDMS, Micro Resist Technology GmbH mr-NIL210, or other bondable material having low surface energy (e.g. Dow Corning Sylgard® 184 silicone elastomer). Additionally, there are two competing, almost mutually exclusive requirements, which lead to an optimized design incorporating the use of two compliant materials. For replication or imprinting of nanometer features, it is preferable to imprint into materials having low viscosity and, optionally, low surface energy, which is most controllable in thin thicknesses, such as photoresist materials which are available for nominal 100 nm to 500 nm thicknesses (e.g. of the type used in a typical wafer replication process). The pattern transfer or imprinting from the linear dimensions of master surface-relief pattern 112 to the outer surface of cylinder 140, however, requires a considerable length of contact, such as along the above described z-axis direction, to allow for sufficient flow and contact and also for achieving the required degree of curing via photopolymerization reactions initiated by actinic radiation received from light source 160. Furthermore, the curing step is preferably under conditions of continuous contact and pressure to achieve the extent of photopolymerization required due to an increase in viscosity of the photopolymer coating material via chain extension and network formation. The use of a compliant material precoat around the circumference of cylinder 140 can be advantageous in decoupling the compliant material precoated master surface-relief pattern 112, which preferably exhibits a low coefficient of linear contraction.

FIG. 4 illustrates the multi-coating embodiment described above and is useful in understanding how the embodiment solves certain challenging problems generally encountered in nanoimprinting. First, there must be sufficient compressive force exerted on both the master replicating surface (i.e. pattern 112) and the imprinting transfer surface (i.e. the outer surface of cylinder 140) during the photocuring step to achieve desired fidelity in the imprinted cylindrical surface-relief patterned mask 135. In the above-described example, wherein light from light source 160 is imaged to the minimum achievable size, the cure zone requires about a 2 mm lead in and 2 mm exit distance along the z-axis direction. The compliant material into which the master surface-relief pattern 112 is imprinted must tolerate sufficient compression to compensate for the change in the gap dimension between the outer surface of cylinder 140 and the flat surface of master 105 over this translation distance in the cure zone. In FIG. 4, the change in gap dimension within the cure zone is depicted as H3-H2 and the resulting strain in the compliant material is (H3-H2)/H3. An example compliant material, such as PDMS, exhibits maximum reversible compressive strain of about 20%. Therefore, the thickness H3 of compliant material is preferably selected such that (H3-H2)/H3≤20% (or otherwise within the elastic regime of an alternative photopolymer material's compressive strain). Since contact with the compliant material into which master surface-relief pattern 112 is imprinted will start immediately prior to entering the curing zone, actual compression will occur first at the gap dimension depicted as H4. Therefore, the compressive strain of the compliant material, which equates to (H4-H2)/H4, is preferably ≤20% for PDMS (or otherwise within the elastic regime of an alternative photopolymer material's compressive strain). Further, the effective diameter of cylinder 140 during the imprinting step is equal to the sum of the diameter of cylinder 140 and the thickness (H4-H2) of the compressed photopolymer material. The calculated diameter is therefore preferably matched, using techniques as described above, such that one full revolution about axis 130 corresponds to the linear distance of the master surface-relief pattern 112 along the z-direction. Through such matching, cylindrical surface-relief patterned mask 135 is produced without a gap between its adjacent ends. Under free state conditions, the imprinted pattern can then be scaled linearly by the ratio of (cylinder diameter+H4)/(cylinder diameter+(H4-H2)). The effect of the compression induced change in diameter can alternatively be tolerated by exerting the same degree of compression strain on the compliant material during construction of cylindrical surface-relief patterned mask 135 as during its subsequent use in the replication of roll-to-roll copy media (e.g. in apparatus 200). In this manner, the mask diameter would be substantially identical in both applications.

The value of the gap dimension set for H3 is a function of the diameter of cylinder 140 which, in turn, is a function of the desired linear length of master surface-relief pattern 112 along the z-direction.

TABLE 2

| Master Cylinder Rod T | | | | | |
|---|---|---|---|---|---|
| Diameter | 31.83099 | 47.74649 | 63.66198 | 95.49297 | mm |
| Circumference (length) | 100 | 150 | 200 | 300 | mm |
| Exposure | | | | | |
| LED Width | 4 | | | | mm |
| Exposure Begin T0 | −2 | | | | mm |
| Exposure Begin (H3-H2) | 0.126164 | 0.083923 | 0.062894 | 0.041906 | mm |
| Mechanical | | | | | |
| Max PDMS Strain | 0.2 | | | | |
| Min. Compliant | 630.82 | 419.62 | 314.47 | 209.53 | μm |
| Thickness (H3) | | | | | |
| Compliant material E | 3.84E+06 | | | | Pa |
| Compression Area | 0.0002 | 0.0003 | 0.0004 | 0.0006 | m\hat{ }2 |
| Force | 153.60 | 230.40 | 307.20 | 460.80 | N |

The significant thickness of a backing layer material coated on cylinder 140 can provide not only a compliant surface but also a significant monolithic structural sleeve around the cylinder. PDMS is commonly used as a desirable molding material because of its transparency, and its exceptionally low surface energy (19.8 mN/m), which is even slightly lower than Polytetrafluoroethylene (PTFE). Due to its inherent characteristics, PDMS exhibits low adhesion with most other materials. However, it should be noted that PDMS adheres very well to itself. Therefore, a monolithic structural sleeve constructed of PDMS does not require a significant degree of adhesion to cylinder 140, since the PDMS sleeve adheres well to additional PDMS layers used in the transfer of master surface-relief pattern 112.

The thickness of the second PDMS layer into which the master surface-relief pattern 112 is imprinted needs to be greater than the depth of the deepest features in master surface-relief pattern 112, which in FIG. 4 is depicted as thickness (H1-H0). The flat master can be coated directly with the specific thickness of photopolymerizable material that is required for imprinting micro and/or nanoscale features. For instance, coating of the flat master can be achieved using conventional spin coating methods, which are adjusted for selected parameters such as speed, temperature and time, in order to achieve a thickness range of 0.1 micron to 0.5 microns. The precise application of compliant transparent coatings onto flat master 105 may be achieved within apparatus 100 using rotary stage 115 as a spin coater that spins off excess material deposited onto master 105. Alternatively, preparation of such coatings used in the imprinting of master surface-relief pattern 112 can be accomplished off line (i.e. through separate preparation of the flat master surface or the cylinder surface).

In a further embodiment, it is to be understood that certain designated areas on master 105 are not intended to be imprinted or transferred to cylinder 140 (e.g. regions outside of master surface-relief pattern 112 along either the z-axis or x-axis direction or regions beyond the lateral dimensions of master 105 on top major surface 125). If such regions become coated with the compliant photopolymerizable material, it is preferred that the photopolymerizable material within these regions be separately cured, or fixed, to prevent contamination of the surface of cylinder 140 during overlap. Selective curing can be accomplished by heating master 105 in these regions or by moving master 105 using translation stage element 110, or other similar translation stage elements, to acutely position such regions directly beneath cylinder 140 and into direct exposure to actinic radiation propagating from light source 160. In the latter method, exposure light can be suitably shaped by cylindrical optical elements 165 and 140 to be a line or bar of desirable length and position along the x-and z-directions by (i) controlling the separation distance between the optical elements 165 and 140 (e.g. using translation element 190 mounted to holding fixture 198 to control their separation distance along the y-axis direction), (ii) controlling the separation distance between optical element 140 and master 105 (e.g. by using translation element 195 to control their separation along the y-axis direction), (iii) controlling the separation distance between optical element 165 and light source 160, and/or (iv) by controlling which light source elements of light source 160 are activated. To assist in the selective curing process, light source 160, as described above, can comprise, for example, a grouping of LED elements or laser diodes arranged in rows or other patterns that can be independently activated to emit actinic radiation in a defined configuration, such as along the x-axis direction. The location of the resulting imaged actinic radiation that is propagated by optical element 140 can thereby be controlled to photocure or fix specific areas on master 105 (or top major surface 125) that are not intended to be imprinted or transferred to cylinder 140. For example, the lead in and lead out regions of photopolymerizable material can be selectively and independently cured, such as by exposure of said regions to an irradiance selected based on the type of photopolymerizable material (e.g. in the range of about 0.5 to 2 joules/cm²). Alternatively, the coating of the compliant photopolymerizable material can be accomplished in a pre-patterned manner, such through inkjet printing or other similar methods for controllably dispensing a volume of material in a desired imprinting pattern.

In another embodiment, seamless, cylindrical, patterned mask 135 can be manufactured using a flat master 105 that has a featureless or pre-cured region. For example, flat master 105 may include such a region at a distance from the center of the cylinder 140 that is at least one-half of the cure zone length (i.e. the position of the outer surface of cylinder 140 that is at the closest contact distance to the master 105 along the y-axis direction). This procedure ensures that the photopolymerizable material receives the required irradiance for achieving the desired extent of curing in the cure zone. As such, at the location when extensional strain is to cause transfer of the imprinted features to the outer surface of cylinder 140, there is a clean peel, or separation, of the cured material from flat master 105 to the outer surface of cylinder 140. The use of a featureless section on master 105 minimizes the residual layer thickness since it will be printed over. Therefore, the actual stroke will correspond to the target length plus the one-half cure length or length of the flat section prior to start. In other words, to produce an overlap, the translation stage moves away from the cylinder in a direction orthogonal to the original direction of motion at the end of the stroke. The transferred imprinted feature pattern can additionally be further irradiated or heated as part of a post curing step provided to achieve the desired extent of polymerization and/or crosslinking for fidelity and robustness of the imprinted feature pattern.

Machining cylinder 140 to the target diameter has been described above. Cylinder 140, by way of example, without limitation, can be constructed of quartz, fused silica, or an optically clear, semi-crystalline or an amorphous polymer, such as a thermoplastic polymer or a polymer resin (e.g. an acrylate or methacrylate, such as poly(methyl methacrylate), or a poly(aryletherketone) such as polyether ether ketone or polyetherketoneketone, or a polyvinyl butyral such as Butvar®, or an aliphatic polyurethane resin, an epoxy resin, a polyester resin, or a cyclic olefin copolymer such as TOPAS®, or an ethylene-tetrafluroethylene copolymer such as Tefzel®). In addition to one of the foregoing materials, cylinder 140 may further include an outer coating of compliant material, the outer coating being of a desired thickness. By way of example, the compliant surface may be constructed using polydimethylsiloxane (PDMS) or other organosilicon material. However, use of such materials renders machining of the outer coating to be challenging using traditional technicques due to the rubbery behavior of the material, which exhibits a high coefficient of friction on any cutting tools. PDMS has a very low glass transition temperature of about −125 degrees C. Accordingly, a cooling nozzle at the end of cooling delivery line 185 can be disposed immediately in front of a single point diamond turning tool 195 positioned on a translation mounting element 170. A coolant, such as liquid nitrogen, can thus be delivered from supply tank 180 as a small localized stream with a cooling temperature of less than about −175° C. In this manner, the dispensed coolant can be used to control the temperature of the surface layer of cylinder 140 to about twice the cutting depth provided by diamond turning tool 195 (about 5-50 microns), thereby resulting in sufficient cooling of the compliant surface layer that is required in order to achieve an exceptionally clean and precise cut. The flow rate of dispensed coolant is dependent on cutting velocity, which is necessarily slow to allow for thermal diffusion to the targeted cutting depth.

### Roll-to-Roll Nanoimprint Lithography Apparatus 201

With cylindrical mask 135 formed in the manner as set forth above, apparatus 100 can be modified slightly in construction and, in turn, directly integrated into a roll-to-roll copying or replication apparatus 201, as shown in FIG. 3.

As can be seen, apparatus 201 comprises selected components of apparatus 100 as well as certain additional elements including, but not limited to (i) a roll-to-roll replication medium, or web, driven by a drive unit, the web having a substrate with a top coated surface 230, (ii) a supply roller 225, such as a vacuum roller, mounted in a vertical framing, or board, and capable of contacting the uncoated side of the web, (iii) a pinch roller 205, which provides force, via piston or linear actuator 235, onto the wetted web surface and into fluid pressure against embossing drum or roller 200 (corresponding to patterned cylinder 140 in apparatus 100) so as to drive fluid flow into the pattern features.

Embossing drum 200 optionally includes a coating unit (not shown) to dispense and coat top surface 230 of the replication substrate. Drum 200, which is preferably constructed as a cylinder coated with a compliant layer, is preferably adjustable in position along the y-axis in order to optimally set its separation distance away from the coated roll-to-roll replication medium.

Apparatus 201 is additionally shown comprising (i) a second guide and/or stripping roller 215, (ii) a vacuum take up roller 220 driven by a drive unit, (iii) light source 160 and optical element 165 from apparatus 100, which together provide actinic radiation for photopolymerization of the imprinted coating on the surface of the roll-to-roll replication substrate, (iv) linear translation elements 110 and 195, (v) rotary control element 115, and (vi) any other elements of apparatus 100 that may be useful in apparatus 201 including, but not limited to, various drive units for controlling rotational angle resolution and velocity, including optical encoders capable of driving the rollers with differential speeds. Lastly, apparatus 201 may be equipped to apply an additional protective coating onto the copy imprinted surface 240 of the roll-to-roll replication medium, if needed.

The embodiments shown above are intended to be merely exemplary and those skilled in the art shall be able to make numerous variations and modifications to it without departing from the spirit of the present invention. All such variations and modifications are intended to be within the scope of the present invention as defined in the appended claims.

What is claimed is:

1. A system for manufacturing a cylindrical nanoimprint lithography master with a feature pattern, the system comprising:
(a) a generally flat master with an externally patterned surface;
(b) a generally cylindrical master having an outer surface disposed in a near tangential relationship relative to the externally patterned surface of the generally flat master;
(c) a light source for producing light; and
(d) a compliant photopolymer material applied onto at least one of the externally patterned surface of the generally flat master and the outer surface of the generally cylindrical master;
(e) wherein the generally cylindrical master is disposed such that a portion of the compliant photopolymer material is continuously maintained in a compressed state through a region of contact established between the outer surface of the generally cylindrical master and the externally patterned surface of the generally flat master, the compliant photopolymer material receiving the feature pattern from the externally patterned surface through the region of contact;
(f) wherein light produced from the light source cures at least a portion of the compliant photopolymer material within the region of contact.

2. The system as claimed in claim 1 wherein the cured compliant photopolymer material is permanently bonded to the outer surface of the generally cylindrical master.

3. The system as claimed in claim 2 wherein the compliant photopolymer material exhibits compressive strain within the region of contact in the range from approximately 5% to approximately 20%.

4. The system as claimed in claim 3 wherein the compliant photopolymer material is preferably polydimethylsiloxane (PDMS).

5. The system as claimed in claim 3 wherein the compliant photopolymer material includes a first layer of compliant photopolymer material applied onto the externally patterned surface of the generally flat master and a second layer of compliant photopolymer material applied onto the outer surface of the generally cylindrical master.

6. The system as claimed in claim 5 wherein the first layer of compliant photopolymer material bonds to the second layer of compliant photopolymer material within the region of contact.

7. The system as claimed in claim 6 wherein the first layer of compliant photopolymer material releases from the externally patterned surface of the generally flat master after bonding to the second layer of compliant material on the generally cylindrical master.

8. The system as claimed in claim 3 wherein the generally flat master is adapted for linear displacement.

9. The system as claimed in claim 8 wherein the generally cylindrical master is adapted for rotational displacement.

10. The system as claimed in claim 9 wherein the generally flat master is linearly displaced at a first translation rate.

11. The system as claimed in claim 10 wherein the generally cylindrical master is displaced at a first rotational rate which is synchronized with the first translation rate of the generally flat master.

12. The system as claimed in claim 11 wherein the externally patterned surface on the generally flat master has a length and wherein the generally cylindrical master has a diameter, the length of the externally patterned surface on the generally flat master being equal to the circumference of the generally cylindrical master.

13. The system as claimed in claim 3 further comprising an optical element that, at least in part, directs light from the light source onto the compliant photopolymer material within a curing zone located within the region of contact.

14. The system as claimed in claim 13 wherein the generally cylindrical master is constructed of an optically transparent material.

15. The system as claimed in claim 14 wherein the optical element directs light from the light source into the generally cylindrical master.

16. The system as claimed in claim 15 wherein the optical element and the generally cylindrical master focus light from the light source into the curing zone within the region of contact.
